(19) United States
(12) Patent Application Publication
(10) Pub. No.: US 2014/0375335 A1
(43) Pub. Date: Dec. 25, 2014

(54) HANDHELD MULTISENSOR CONTRABAND DETECTOR TO IMPROVE INSPECTION OF PERSONNEL AT CHECKPOINTS

(71) Applicants: James Winso, Escondido, CA (US); John Rolando, La Mesa, CA (US); Thomas Schaenzler, Vista, CA (US); Eric S. Ackermann, San Diego, CA (US)

(72) Inventors: James Winso, Escondido, CA (US); John Rolando, La Mesa, CA (US); Thomas Schaenzler, Vista, CA (US); Eric S. Ackermann, San Diego, CA (US)

(73) Assignee: SPECTRAL LABS INCORPORATED, San Diego, CA (US)

(21) Appl. No.: 13/594,717

(22) Filed: Aug. 24, 2012

Related U.S. Application Data
(60) Provisional application No. 61/528,114, filed on Aug. 26, 2011.

(51) Int. Cl. G01N 22/00; G01N 29/04; G01V 3/10; G01R 1/04; G01N 29/36

(52) U.S. Cl. CPC G01N 22/00; G01R 1/04; G01N 29/36; G01V 3/10; G01N 29/04; G01N 2291/045
USPC 324/637

(57) ABSTRACT

A handheld apparatus for measuring natural microwave electromagnetic radiation emanating from a human body to detect areas of anomalous emissions indicating concealed contraband is disclosed. In a particular embodiment the apparatus includes at least two radiometers directed toward a common viewing plane. Circuitry converts the strength of the microwave emissions into a spatially indexed electrical signal related to the localized intensity of the emanations. The lack of need for highly precise spatial resolution allows the use of a region of the microwave spectrum with an abundance of low cost components. A processing system is configured to analyze the time dependent signal from each radiometer during the scanning of a subject. Additional confirmation sensors that measure the body's acoustical reflection capability and metal content supplement the microwave measurements to provide more robust readings. Methods for determination of the relative position of the anomalous reading and communicating with the operator are discussed.

### CROSS REFERENCE TO RELATED APPLICATIONS

This application claims the benefit of U.S. Provisional Patent App. No. 61/528,114 filed on Aug. 26, 2011, the entirety of which is hereby incorporated by reference.

### STATEMENT REGARDING FEDERALLY SPONSORED RESEARCH OR DEVELOPMENT

This invention was made with government support under Small Business Innovative Research Contracts DP10PC20055 and DP11PC20186 awarded by the United States of America Department of Homeland Security. The government has certain rights in the invention.

### BACKGROUND OF THE INVENTION

1. Field of the Invention

The present subject matter relates generally to checkpoint inspection devices, and in particular to compact detector ensembles that enable detection of metallic and non-metallic contraband in a single hand held instrument. In particular it discloses an instrument based on measuring the natural microwave radio emissions and reflections of materials and persons and fusing the resultant data with outputs from complementary sensors to confirm results.

2. Description of the Related Art

Checkpoint screening has become essential to ensure the safety of air, rail and sea passengers, the security of high profile events (e.g. sporting events, a presidential inauguration) and the protection of critical buildings and infrastructures. The United States government has identified a vital need to advance the state of the art of available portals and hand-held devices to better support law enforcement staff responsible for detecting concealed person borne contraband and threat material at personnel checkpoints. It is important that the technologies deployed do not infringe on the privacy of the public or require physical contact. This issue is complicated by the fact that throughput is very important and there is an unlimited set of concealment methods and masking materials. Thus identification of illicit material must be acquired quickly to facilitate real time decisions even in the presence of obscurants and masking agents.

Handheld metal detectors are widely used for checkpoint screening. The passive metal detectors are designed to detect ferrous materials. Active metal detectors excite eddy currents in conductive materials and measure their magnetic response. Due to the low conductivity of many ferrous materials the active systems are less effective in detecting ferrous metals. Metal detectors are inexpensive, easy to use, and nonintrusive. They can also support a high throughput rate. However, since they cannot detect nonmetallic materials they are not sufficient for most checkpoint applications without secondary screening equipment. The need is for a handheld tool that will exhibit the inherent advantages of metal detectors and also detect nonmetallic contraband.

Another example of an effort to address the checkpoint screening issue is the Advanced Imaging Technology (AIT) devices being deployed by the United States Transportation Security Administration (TSA). AIT allows security personnel at airports check points to detect hidden items on passengers by using imaging technologies that reveal details of the human body in high-resolution images. These AIT Systems use low energy X-Rays, Active Millimeter Wave Interrogation, or Passive Millimeter Wave emissions from the subject passing through the system to create an image that can reveal anomalies.

The use of these AIT Systems and their potential for real or perceived privacy violations has created a great deal of controversy among airline passengers, pilots, support personnel, and airport staff. Additionally, they are quite expensive, result in delays at the checkpoints, and require significant infrastructure and specialized training for operators. Because of privacy issues, they require inspectors reviewing the images to be accommodated remotely from the checkpoint to ensure that they do not interact with the subject being inspected. Although Airport Security Checkpoints are frequently located in controlled environments with available utility services, checkpoints can also be required in uncontrolled locations, indoor and outdoor, which can significantly affect the practicality of AIT systems. Moreover, the cost of the AIT Systems makes them unrealistic for use at most border crossings, building security check points and at ad hoc locations set up for special events.

Thus a need exists for an apparatus that can detect concealed metallic and non-metallic materials and do so in a handheld device that has a high probability of detection and a low probability of false alarms. Some inspection wands are based on measurement of high frequency, e.g. W band, millimeter or Terahertz waves. Such devices can provide high precision of target location of the person being inspected, but are limited based on the impact of obscurants, their high cost, and reliability issues associated with a relatively new technology working at the edge of feasibility. Predictable performance of such devices in an extensive set of environments and applications without requiring optimization of each sensor or placing demands on the operator to interpret results based on environmental parameters at the point of inspection has not been achieved.

This patent discloses a practical handheld device that employs a suite of sensors that operate in a more favorable measurement region and allows for using readings from orthogonal sensors (such as the metal detectors discussed) for confirmation of contraband presence. This approach provides robust detection against a wide range of concealment strategies with an enhanced ratio of detection probability versus probability of false positives. This design can employ lower cost individual sensors because of the confirmation capability of multiple sensors and would be more effective against an expanded set of contraband species. The design would not depend upon imaging, as is the case with AIT Whole Body Imagers, thus personal privacy would not be an issue. The invention does not require operator interpretation of images and the special training required to make such interpretations. It would instead provide a simple “Go-No Go” indication of the presence of hidden material. It was not obvious to the industry how this need could be fulfilled at the time of the present invention.

### SUMMARY OF THE INVENTION

A handheld apparatus for measuring natural microwave electromagnetic radiation emanating from a human body to detect areas of anomalous emissions indicating concealed contraband is disclosed. In a particular embodiment the apparatus includes at least two radiometers directed toward a common viewing plane. Circuitry converts the strength of the microwave emissions into a spatially indexed electrical signal related to the localized intensity of the emanations. The lack of need for highly precise spatial resolution allows the use of a region of the microwave spectrum with an abundance of low cost components. A processing system is configured to analyze the time dependent signal from each radiometer during the scanning of a subject. Additional confirmation sensors that measure the body's acoustical reflection capability and metal content supplement the microwave measurements to provide more robust readings. Methods for determination of the relative position of the anomalous reading and communicating with the operator are discussed.

The invention enables a compact, hand held instrument that can quickly detect metallic and non-metallic threats at checkpoints with a very favorable true positive to false positive ratio. It would be deployed much as are current day Metal Detection Wands. The difference is that, in addition to detecting metal, the invention would be capable of quickly detecting nonmetallic materials such as ceramics, plastics, explosives, cash, or drugs. The essence of the invention is to employ a suite of two or more Total Power Radiometers (TPRs) to measure natural electromagnetic emissions in the K and/or Ka microwave radio bands and to augment the TPR suite's performance with complementary sensors. Although the definition of microwave radio bands varies widely from such industry and government sources as the IEEE, International Telecommunications Union, the FCC, the Radio Society of Great Britain, and NATO, common definitions limit the K band to the range from 18 GHz to 26.5 GHz and the Ka band to the range from 26.5 GHz to 40 GHz. As will be discussed below, employing radiometers in this band provides abundant technical and commercial benefits. Embodiments of the invention also employ an Active Ultrasonic Module that measures return from transmitted ultrasonic signals and/or a customized induction based Metal Detection Module to supplement the TPR Suite.

The multisensor suite of TPRs in conjunction with supplemental Modules allows for a faster scan rate, minimizing the scan time to sense the presence of concealed contraband. Experimental data shows that each contraband detection sensor has deficiencies depending upon the type and quantity of the hidden material, methods used to conceal the materials, and the ambient environmental conditions at the screening location. Increasing the sensitivity of any single sensor increases the probability of false positive alarms causing unacceptable screening delays. Portable handheld operation enables flexible deployment without the need for facility or infrastructure investments. The invention takes advantage of the fact that no imaging would be provided. This obviates personal privacy issues as well as specialized operator training. Embodiments housed in a package weighing less than 2 kg are disclosed.

Total Power Radiometers are sensitive radio receivers that measure incident electromagnetic radiation from the environment within a defined frequency band. The amount of radiation being emitted from a specific object depends on two components: 1) radiation emitting from the object due to it having a physical temperature higher than absolute zero which is a function of its absolute temperature and its intrinsic emissivity, and 2) radiation due to the target reflecting radiation from its surroundings. The overall emissions of the human body are somewhat consistent depending on the environment and vary from contraband emissions, which depend on the object's temperature as well as its emissivity and reflectivity constants. Fortuitously, most clothing items are transparent to the radiation, particularly in the K and Ka bands being measured by the invention. The invention employs a suite of Total Power Radiometers each measuring the emissions from a different spatial position on the subject being inspected to enable detection of differences in the total power between each TPR employed in the invention and also changes over time on each TPR as the field-of-view passes by the subject being inspected. Changes in the measured power from objects that are either at a different temperature or with different emissivity and reflectivity material properties or both, compared to the human body would signal an anomaly.

Natural emissions in the K and Ka band compared to the W and higher millimeter wave bands are about an order of magnitude lower. This results in less total power being received by the invention and consequently a lower signal level into the radiometer than would be the case if a higher frequency were being observed. However this is more than offset by the lower noise generation and stability of K and Ka band radiometers compared to the W band and higher frequency devices. This is particularly important in handheld devices that experience continual movement and shocks while being employed. Another characteristic of the invention resulting from measuring in the K and Ka band is that the components are larger and thus the Total Power Radiometers do not provide the high spatial resolution (often 5 millimeter (0.2 inches) or less) available from the W band whole body imagers. The spatial resolution for the invention is a function of the scan speed, but is generally able to detect contraband with a cross section diameter of 2.5 centimeters (1 inch) or greater. However, as will be appreciated by those skilled in the art, being able to reliably detect contraband of this size or larger in a handheld non imaging detector will be a great benefit to the community.

The inherent advantages of exploiting the K and Ka band versus the W and higher millimeter bands includes the ability to employ low cost feed-horn antennae versus the quasi-optic lens systems required for higher frequency designs and having a wider Field of View (FOV) permitting more complete coverage of the subject with fewer Total Power Radiometers. Additionally, since the K and Ka band have been commonly used for satellite and cell phone communications and radio navigation for over a decade, the invention will enjoy access to considerably lower cost components with the reliability that evolves from a mature technology. Obscurants including layers of clothing are also more transparent to the emissions in this lower frequency band and provide an acceptable Signal to Noise ratio even with the lower base emitted by the subject in the K and Ka band. Additionally, the technical challenges of producing reliable, low cost detectors are more readily addressed in the K and Ka band since the circuit dimensions are larger and do not require the precision tolerances of higher frequency devices. This leads to intrinsically lower material and assembly cost, more consistent product quality enabling wider deployment, and a fundamentally more rugged device for handheld applications.

An additional handheld multisensor contraband detector measuring system includes an Active Ultrasonic Module that includes an ultrasonic transmitter with an array of reflection measurement sensors. An ultrasonic sensor is well-matched to complement the Total Power Radiometer sensors since the ultrasonic reflections respond to different physical phenomena, namely acoustic impedance at material boundaries. Embodiments of the Active Ultrasonic Module could employ dual frequencies to enable material classification. Other Active Ultrasonic Module embodiments could employ phased array software that will provide improved spatial location of targets.

A particular embodiment of the handheld multisensor contraband detector would employ a suite of more than two K or Ka Total Power Radiometers, an Active Ultrasonic Module and a Metal Detection Module including an inductive metal detector with a coil loop customized for the invention's application. Another particular embodiment of the handheld multisensor contraband detector would employ a suite of more than two K or Ka Total Power Radiometers and a Metal Detection Module including an inductive metal detector with a coil loop customized for the detector application. Other particular embodiments of the handheld multisensor contraband detector would employ a suite of more than two Total Power Radiometers tuned to different frequency ranges within the K or Ka bands. Another particular embodiment of the handheld multisensor contraband detector would employ two K or Ka Total Power Radiometers, a Rotating Mirror, one at each end of the detector, to enable scanning parallel to the detector length, a set of ultrasonic transmitters and an array of microphones, and an inductive metal detector with a coil loop customized for the detector application. Another particular embodiment of the handheld multisensor contraband detector would employ two K or Ka Total Power Radiometers, one at each end of the detector, a Rotating Mirror to enable scanning parallel to the detector length and an inductive metal detector with a coil loop customized for the detector application. Another particular embodiment of the handheld multisensor contraband detector would employ two K or Ka Total Power Radiometers, one at each end of the detector, and a Rotating Mirror to enable scanning parallel to the detector length.

The position of the concealed material would be approximated by visual, LED indicators placed along the length of the detector. Audio and vibration indications could also designate the presence of an anomaly. Headsets would be provided to enable the operator to covertly detect an anomaly. The Ultrasonic Subsystem would also provide range and attitude of the detector relative to the subject being inspected. An additional set of LED indicators would be provided near the detector's handle to warn the operator if the position of the detector relative to the subject being inspected needs to be changed. Power would be provided by rechargeable batteries. The invention will employ a custom designed signal processing system to exploit the sensor responses.

It is a principal object of the invention to provide a device for the identification of illicit material.

It is another object of the invention to provide a device that quickly identifies illicit material to facilitate real time decisions.

It is an additional object of the invention to provide a device that identifies illicit material even in the presence of obscurants and masking agents.

It is a further object of this invention to provide a device that does not infringe on the privacy of the public or require physical contact.

In a particular embodiment, the invention is a handheld multisensory contraband detector comprising a plurality of K or Ka band Total Power Radiometers, where each Total Power Radiometer measures the power of natural microwave emissions from different spatial locations of a subject, an Active Ultrasonic Module, where the Active Ultrasonic Module comprises an ultrasonic transmitter, an ultrasonic sensor, and a phased array processer, where the phased array processor provides the position of ultrasonic return signals obtained by the ultrasonic sensor, a Metal Detection Module, a processor board, wherein the processor board processes signals from the Total Power Radiometers, phased array processor, and metal detector, where the processor board calculates a confidence factor of whether or not an anomaly on a subject has been encountered, and an enclosure package, where the enclosure package provides environmental protection to the detectors, sensors, and processors of the handheld multisensory contraband detector.

In another embodiment, the invention is an apparatus for detecting anomalous signals from a subject being scanned, the apparatus being comprised of an aligned suite of detectors comprised of more than two K or Ka band Total Power Radiometers to measure the power of natural microwave emissions from different spatial locations of the subject; a processing system to monitor variances between each Total Power Radiometer to determine if an anomaly is present during the scan; and an enclosure package to provide environmental protection to the Total Power Radiometers.

In yet another embodiment, the invention is an apparatus for detecting anomalous signals from a subject being scanned, the apparatus being comprised of an aligned suite of detectors comprised of more than two K or Ka band Total Power Radiometers to measure the power of natural microwave emissions from different spatial locations of the subject; a processing system to monitor variances between each Total Power Radiometer to determine if an anomaly is present during the scan; an enclosure package to provide environmental protection to the Total Power Radiometers; a click scan Start/Stop button, wherein depressing the click scan Start/Stop button indicates the beginning and end of a scan; a scan speed sensor; a processing system to integrate the signal strength from each Total Power Radiometer over a discrete time slice required to transverse a small section of a body during a scan; a processing system to time stamp and store the integrated signal strength for each Total Power Radiometer indexed by its corresponding time slice in accessible digital memory; a processing system to convert a temporal variance between each integration period along with an instantaneous scan speed into a spatial dimension roughly orthogonal to the axis of the aligned suite of detectors; a processing system to map the time related integrated signal strength of each Total Power Radiometer onto a Two Dimensional Spatial Data Matrix; a processing system to facilitate analysis of the Two Dimensional Spatial Data Matrix upon completion of the scan to provide a higher probability of anomaly detection; and wherein the processing system to facilitate analysis of the Two Dimensional Spatial Matrix produces an alert signal based on the Two Dimensional Spatial Data Matrix analysis to suggest a repeat scan at a slower scan speed.

In an additional embodiment, the invention is a handheld multisensor contraband detector, comprised of two K or Ka band Total Power Radiometers to measure natural microwave emissions; a rotating mirror to sweep a scanning zone from each Total Power Radiometer across the surface of a subject being inspected from each end of the detector; a high speed switching system to define a discrete time slice required for the scanning zone being swept by the rotating mirror to transverse a defined small angle of the subject being inspected; a processing system to integrate the signal strength over the discrete time slice required for the scanning zone being swept by the rotating mirror to transverse a small angle of the subject being inspected; a processing system to time stamp and store the integrated signal strength for each scanning zone swept by the rotating mirror in accessible digital memory; a click scan Start/Stop button to indicate the beginning and end of a scan; a scan speed sensor; a processing system to map time related variance of the signal strength of each scanning zone onto a Two Dimensional Spatial Matrix to determine if an anomaly is present; a processing system to facilitate analysis of the Two Dimensional Spatial Data Matrix upon completion of a scan to provide a higher probability of anomaly detection; and an enclosure package to provide environmental protection to the sensors and processing systems contained therein.

There has thus been outlined, rather broadly, the more important features of the invention in order that the detailed description thereof may be better understood, and in order that the present contribution to the art may be better appreciated. There are additional features of the invention that will be described hereinafter and which will form the subject matter of the claims appended hereto. The features listed herein and other features, aspects and advantages of the present invention will become better understood with reference to the following description and appended claims.

### BRIEF DESCRIPTION OF THE FIGURES

The accompanying drawings, which are incorporated in and form a part of this specification, illustrate embodiments of the invention and together with the description, serve to explain the principles of this invention.

FIG. 1 is a Front Perspective View of a handheld multisensor contraband detector employing a Total Power Radiometer Suite, Active Ultrasonic Module and Metal Detection Module according to selected embodiments of the current disclosure;

FIG. 2 is a Rear Perspective View of the handheld multisensor contraband detector shown in FIG. 1;

FIG. 3 is a Front Perspective View of the handheld multisensor contraband detector of FIG. 1 shown without the housing;

FIG. 4 is a Side Perspective View of the handheld multisensor contraband detector of FIG. 1 shown without the housing;

FIG. 5 is a Component Block Diagram of the handheld multisensor contraband detector of FIG. 1;

FIG. 6 is a Functional Diagram of the handheld multisensor contraband detector of FIG. 1;

FIG. 7 is diagram of scanning a body with the handheld multisensor contraband detector of FIG. 1;

FIG. 8 is a Front Perspective View of the handheld multisensory contraband detector employing a Total Power Radiometer Suite and Metal Detection Module shown with the housing made transparent;

FIG. 9 is a Block Diagram of the handheld multisensor contraband detector of FIG. 8;

FIG. 10 is a Front Perspective View of a handheld multisensor contraband detector employing a Total Power Radiometer Suite according to selected embodiments of the current disclosure;

FIG. 11 is a Block Diagram of the handheld multisensor contraband detector of FIG. 10;

FIG. 12 is a Total Power Radiometer Component Block Diagram of particular multisensory contraband detector embodiments of FIGS. 1, 8, and 10;

FIG. 13 is a Total Power Radiometer Component Block Diagram of a handheld multisensor contraband detector employing a rotating mirror according to selected embodiments of the current disclosure.

### DETAILED DESCRIPTION OF THE INVENTION

Many aspects of the invention can be better understood with the references made to the drawings below. The components in the drawings are not necessarily drawn to scale. Instead, emphasis is placed upon clearly illustrating the components of the present invention. Moreover, like reference numerals designate corresponding parts through the several views in the drawings.

The handheld multisensor contraband detector addresses the critical need to improve the capability to detect threats and illegal contraband at personnel checkpoints while optimizing screening efficiency, minimizing wait times and carefully addressing privacy concerns. The handheld multisensor contraband detector is based on detection of natural body emissions in the K and Ka microwave bands with a suite of Total Power Radiometers and fuses the data from these radiometers with an Active Ultrasonic Module and a Metal Detection Module for confirmation. These complementary sensors enable high confidence detection for a much wider range of objects and concealment scenarios than single sensor approaches.

The handheld multisensor contraband detector would be deployed much as are current day metal detection wands and will not present the privacy issues of imaging systems. The difference is that, in addition to detecting metal, the handheld multisensor contraband detector would be capable of quickly detecting nonmetallic materials such as ceramics, explosives, plastics or drugs. Laboratory data has demonstrated that this approach is capable of providing real time, unambiguous indication that hidden contraband is present on a person being screened with both K and Ka band Total Power Radiometers.

Although operating in a significantly lower frequency range, passive microwave and millimeter wave detection works on the same physical principle as infrared (IR) detection. That principle is that all objects above absolute zero (0° K) emit electromagnetic energy dependent on their material properties and their temperature. The amount of thermal emission in the IR range is much greater for most objects and IR sensing is widely exploited. The limitations of IR include an inability to penetrate through clothing and obscurants and the extremely high cost of IR cameras. IR cameras are also bulky and not suitable for a handheld detector. Until recently, technical difficulties have stalled development of sensors for the lower frequency emissions.

The key to the invention's method of detecting anomalies on the human body depends on measuring the differences in the amount of thermal energy emanating from an object relative to that from the human body. The amount of thermal energy being emitted from a specific object depends on two components: 1) radiation emitting from the object due to its physical temperature being higher than absolute zero and 2) radiation due to the target reflecting radiation from its surroundings. The Total Thermal Power (P_{T}) emitted by an object is a simple function of Emissivity and Temperature, (P_{T}=kεT), where k=Boltzmann's constant, ε=the Emissivity of the object, and T is the Thermodynamic or Absolute Temperature (Kelvin or Rankine scale) of the object. The Emissivity is a dimensionless number between 0.0 and 1.0 that is an intrinsic property of the material. Emissivity has a simple balance with Reflectivity (R) in that ε+R=1. Thus materials with a high Reflectivity, such as polished aluminum with R=0.91, have a low Emissivity, ε=0.09. Materials with high Emissivity, such as cardboard with ε=0.8, have a low Reflectivity R=0.2. Human skin has a very high Emissivity of ˜0.98.

By adding the thermal energy emitted by the object plus the thermal energy reflected by an object from its surrounding an Effective Temperature T_{E} of the object is determined. The Effective Temperature of an object with an intrinsic temperature of T_{I} in a surrounding with a temperature of Tₛ can be expressed as:

T_{E}=ε_{I}T_{I}+R_{I}T_{S}; Since ε+R=1; R=1−ε, Thus T_{E}ε_{I}T_{I}+(1−ε_{I})T_{S}

The benchmark for radiometers is the ability to resolve minute differences in the T_{E} from different positions on the subject. This difference, ΔT_{E}, can be calculated by subtracting T_{EO1} for Object 1 (e.g. contraband) from T_{EO1} for Object 2 (e.g. the human body). Clearly a difference in temperature of the object would be helpful, but for the worst case where the contraband and the human body are at the same body temperature, T_{B}, the ΔT_{E} could be calculated as follows:

ΔT_{E}=T_{EO1}−T_{EO2}=ε_{O1}T_{B}+(1−ε_{O1})T_{S}−ε_{O2}T_{B}−(1−ε_{O2})T_{S}, or

ΔT_{E}=(ε_{O1}−ε_{O2})T_{B}+(ε_{O2}−ε_{O1})T_{S}, or

ΔT_{E}=(ε_{O1}−ε_{O2})(T_{B}−T_{S})

Thus, the variance in the effective temperature between the object and the body is a function of the difference in Emissivity between the object and the human body multiplied by the difference in effective temperature between the human body and the surroundings.

The above discussion referred to the total thermal energy being emitted by bodies, but clearly any actual instrument can only measure a given band of the energy. The practical minimum measurable ΔT_{E} is a function of the system temperature (T_{SYS}) divided by the square root of the product of the range of frequencies or Bandwidth being measured (B), and the integration time (τ) as shown here:

$$Δ {T}_{E} ∼ \frac{{T}_{SYS}}{{( τ B )}^{1 / 2}}$$

This relationship shows that higher bandwidth and longer integration times reduce ΔT_{E}, thus improving sensitivity. Another key system design issue is the system temperature, T_{SYS}, which depends on the product of the Noise Figures (NF) from each stage of the radiometer and the ambient radiometer temperature. For a design with M stages T_{SYS} would be expressed as:

T_{SYS}˜NF₁*NF₂*NF₃* . . . NF_{M}

By operating in the K and Ka band, these Noise Figures are significantly minimized improving the temperature resolution. Typically, Passive Millimeter Wave Imagers must be able to measure ΔT_{E} of 0.5° K or less to provide the required imaging perception and Probability of Detection. The invention has demonstrated that a ΔT_{E}<0.3° K can be achieved in the K and Ka band with an integration time of less than 100 milliseconds and a Bandwidth of 3 GHz. Of course any actual intrinsic temperature differences between the contraband and the human body will enhance the Probability of Detection. Thus the invention is able to provide comparable performance to the much more expensive and fragile radiometers being developed in the W Band and above at a cost and ruggedness suitable for a handheld device.

Key features of the handheld multisensor contraband detector are high throughput, ability to discern contraband targets behind a wide range of obscurants, simplified, non-imaging “Go-No Go” indication of the presence of contraband, standalone operation, and low cost. The high throughput capability stems from an integration time of less than 100 milliseconds to discern anomalous targets hidden on a person with a minimum cross section diameter of 2.5 centimeters (1 inch). Most obscurant materials, such as leather jackets, are highly transparent to microwaves in the K and Ka bands, enabling detection in most circumstances. In addition the Active Ultrasonic and Metal Detection Modules will provide confirmation when obscurants are able to block the microwave emissions. The presence of an anomaly will be indicated by simplified audio, visual or vibration alarms that do not require interpretation.

The use of multiple sensors also enables employing relatively low cost techniques and avoiding the exotic and expensive designs required to accurately measure high frequency W Band Millimeter or Terahertz emissions. This approach does not provide high resolution as found in W Band imaging systems, but does provide adequate resolution of 2.5 centimeters (1 inch) to detect anomalies of interest. The multisensor detector stores the data in a Two Dimensional Spatial Data Matrix facilitating an overall scan analysis by a processing algorithm. This technique would be able to detect the variances between signals caused by a multiplicity of smaller targets and suggest a slower rescan by the operator.

The detector will incorporate sensors to guide the operator to maintain the proper standoff with the subject being inspected and will also provide an alert if the scanning speed is excessive. Operation at both indoor and outdoor locations will be adjusted by internal monitors that normalize sensor responses based on environmental conditions. Since the Total Power Radiometers are designed for the K or Ka band, they are much less sensitive to humidity and moisture effects than would be W band or higher frequency sensors. The overall package will be airtight and sealed to practically eliminate any impacts from moisture or dust in extreme weather conditions. Additionally, the ruggedness of the each of the sensors makes the overall instrument much less susceptible to the effects of vibration or high impact shock.

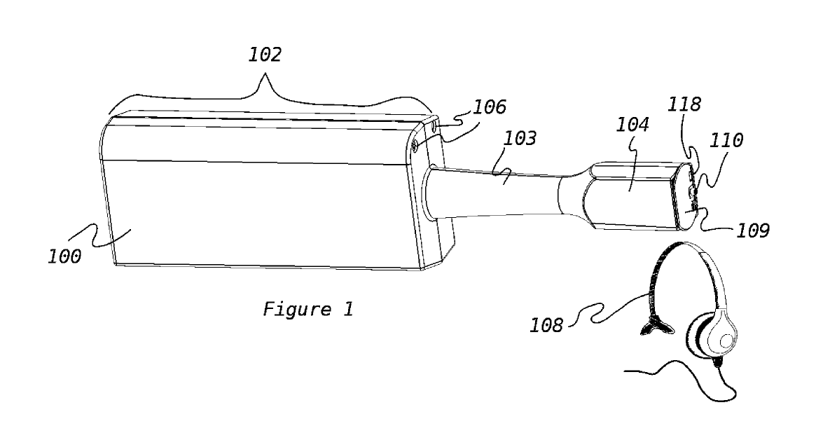

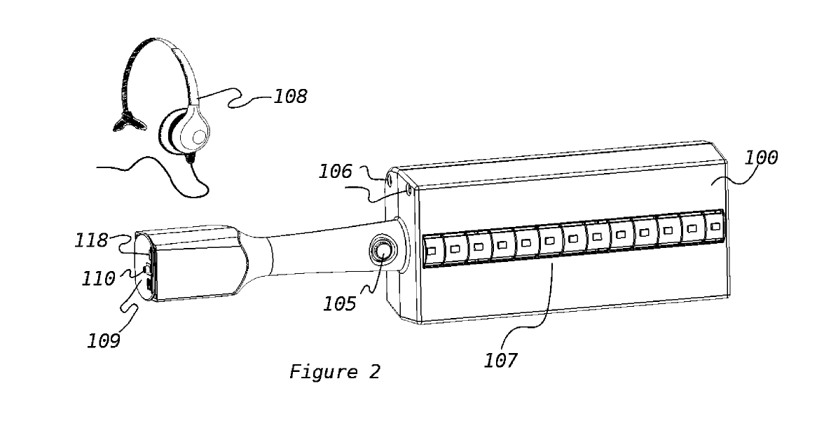

In a first preferred embodiment of the multisensor detector depicted in FIGS. 1 and 2, the system is enclosed by a rugged but lightweight plastic package 100. Although carbon is very absorptive of W band and higher millimeter waves, it is much less significant in the K and Ka bands. Thus considerable latitude will be available to select the most durable and easily sealed package material. The package includes three sections, a unit housing 102 that contains the sensors, power supplies and processing circuits, a grip section of the handle 103 to facilitate easily grasping of the detector by the operator, and a battery pocket 104 that contains the rechargeable battery and interfaces to a headset. The unit housing 102 includes a suite of more than two K or Ka band microwave Total Power Radiometers, a suite of four to six 25-50 KHz ultrasonic transmitters, a suite of at least 24 microphones, and a metal detector coil and processing circuit. The grip section 103 of the handle includes a simple, recessed push button switch 105 that can be depressed for several seconds to turn the unit on or off. When the system is turned on it will perform a self-check diagnostic routine and then enter a ready state. The ready state will be indicated by blinking of the Light Emitting Diodes (LEDs) 106 at the rear of the unit housing. The switch can also be actuated for a scan with a quick click to initiate a scan. During scanning the LEDs 106 at the rear of the unit housing 102 will signal if the probe should be moved closer or further from the subject being inspected. The scans are ideally conducted at a 5 centimeter (2 inches) to 10 centimeter (4 inches) spacing from the target. In addition, during the scan a LED array 107 along the side of the unit housing will indicate the scan mode by illuminating all of the green (normal) lights. The presence of an anomaly will be denoted by either a yellow (alert) or red (alarm) LED, depending on the confidence factor determined by the main processor board discussed in more detail below. An audio tone and a mechanical vibrating motor in the handle will also signify an alarm. The operator can select to silence the audio alarm or to direct it to a headset 108. After the scan is completed, an additional quick click to switch 105 will return the unit to the ready state. The system will sense if the operator does not end the scan and automatically return to the ready condition after a preset time. An end cap 109 on the battery pocket 104 will enable replacement of the rechargeable battery. The end cap 109 will also include a receptacle to accept the headset jack 110 such as a MIL-J-541. Also integrated into the battery pocket and accessible by removing the end cap 109 will be a USB connector that will enable connection to software on a PC platform that will facilitate adjusting alarm thresholds and other performance parameters.

The signal strength readings from each sensor will be collected and integrated at a periodic rate, e.g. 50 milliseconds, during the scan. The results from each integration period for each sensor will be stored in a Two Dimensional Spatial Data Matrix with time and position relative to the sensor being the major axes. In parallel with the data integration and storage, processing will be on going to determine if a significant spatial or temporal variance is observed. If so an alarm will immediately be posted and the relative position noted on the LED array 107. At the end of the scan a more complete analysis of the array data will be conducted to determine if an anomaly is possible. If so, an alert signified by a rapid blinking of the yellow LEDs in the LED array 107 will suggest repeating the scan slowly to the operator. The operator can initiate this subsequent scan by a quick click to switch 105. At the conclusion of a scan the system will be ready for a subsequent scan in less than 1.0 seconds.

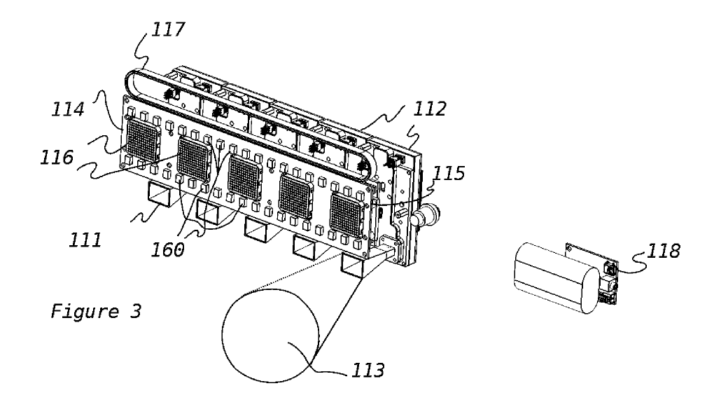

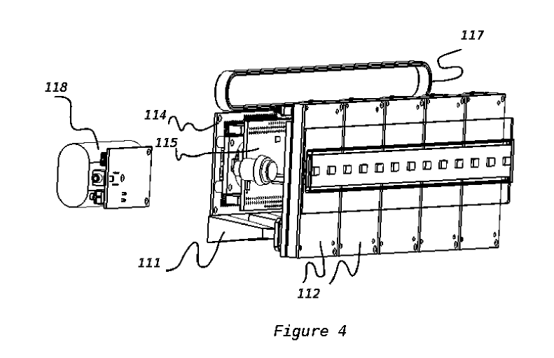

FIGS. 3 and 4 depict the embodiment shown in FIGS. 1 and 2, with the plastic packaging removed. It shows that the radiometer feed horns 111 are connected to the radiometers 112 to collect microwave emissions from the subject being inspected. The K and Ka band Total Power Radiometers are much more robust and cost effective than higher frequency receivers. They are also not as susceptible to rigorous dimension tolerances required by W band radiometers, easing the ability to meet quality standards.

In the depiction of FIGS. 3 and 4, a quantity of five Ka band feed horns with a 15 db gain are shown. Each will collect microwave emissions from a near circular target area 113 which can vary from 2.5 centimeters (1 inch) to 5 centimeters (2 inches) in diameter. This configuration provides the most efficient coverage and does not require the use of lenses as is often the case with W band and higher frequency sensors. Placed forward is the Ultrasonic Printed Circuit Board 114 which houses a processor 115 to perform beam tracking. The ultrasonic transmitters 116 are housed in pockets at the front face of the detector. An array of receiving microphones 160 to receive ultrasonic reflections from the subject is also housed on the Ultrasonic Printed Circuit Board 114. The metal detector coil 117 is also located as close as possible to the front since its sensitivity falls off rapidly with target distance. The USB Connector 118 shown in the Battery Pocket 104 enables adjustment of alarm thresholds and other user preferences (e.g. to silence the alarm) from a PC resident program.

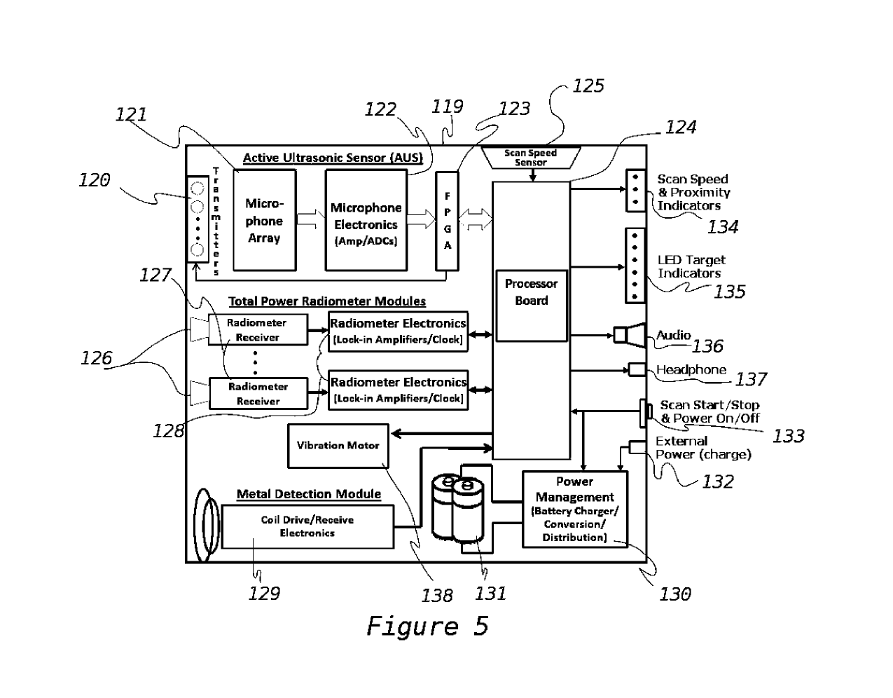

FIG. 5 depicts a Component Block Diagram 119 of the embodiment shown in FIGS. 1 and 2. It includes the internal components and their interconnection. The Ultrasonic Transmitters 120 which illuminate the subject are shown. The return signal is converted by an array of microphones 121 into an electronic signal that is demodulated by the microphone electronics 122 and stored in a Field Programmable Gate Array (FPGA) local processor 123. The local processor develops a signal proportional to the strength of the return and provides a location relative to a reference point on the detector. This signal is sent to the main processor board 124 for processing by the main anomaly detection algorithm. Also providing input to the processor board is a scan speed sensor 125 such as one used for an optical mouse that enables location of received data relative to the initiation point of a scan. The array of feed horn antennae 126 provides input to the Total Power Radiometer for each channel. Each Total Power Radiometer includes a radiometer receiver 127 to collect the electromagnetic emissions and radiometer electronics 128 to control and process the data. Integrated data from each channel is sent to the main processor board 124 and time stamped. A metal detection coil 129 also sends amplitude data to the main processor board 124. The main processor board 124 is comprised of microcomputer and logic circuitry that is capable of executing an analysis program that will calculate a confidence factor that quantifies the likelihood of an alarm. A power management circuit 130 distributes power and enables in-situ charging of the rechargeable batteries 131. An external power jack 132 enables external AC power to be connected to the power management circuit 130. A main switch 133 interfaces with the main process board 124 to turn power on or off as well as to initiate or terminate a scan. Indicators interfacing with the main processor board 124 include LED Scan Speed and Proximity Indicators 134, and a Target Indicator Array 135. The main processor board 124 analyzes the incoming signals to produce a confidence factor that is used, along with a user set threshold, to determine if an alarm should be activated. If so, Audio alarms 136, headset alarms, 137 and vibration alarms 138 are driven from the main processor board 124.

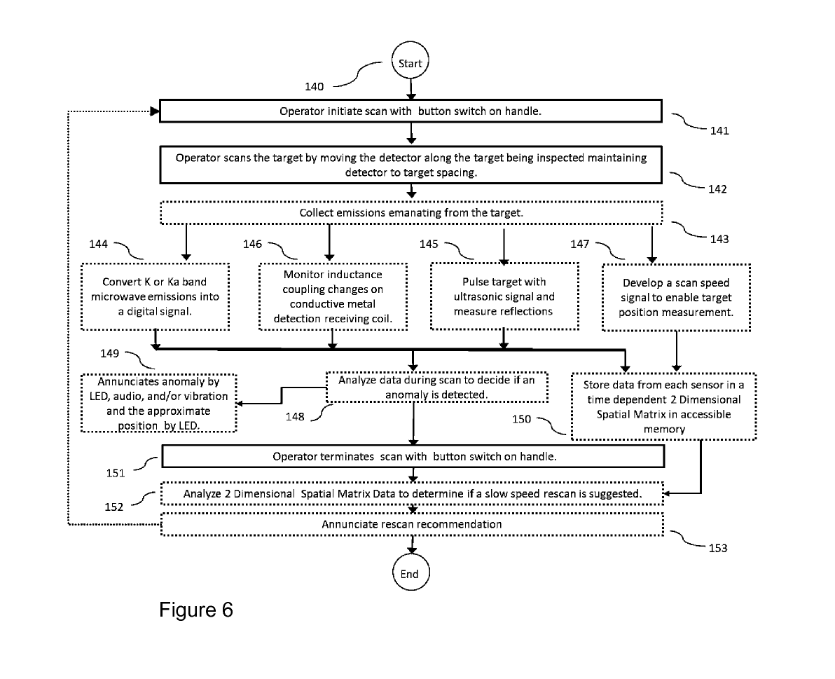

FIG. 6 depicts the signal process flow 140 of the embodiment shown in FIGS. 1 and 2. It shows that the operator initiates a scan 141 by depressing the input button switch 105. The target is scanned 142 by moving the invention along the target maintaining a spacing of 5 centimeters (2 inches) to 10 centimeters (4 inches). Emissions coming from the scanned subject 143, which could be from the trunk or limb of the subject being inspected, are collected in parallel by the detectors. These subject emissions include microwave emissions that are converted to electronic signals 144 by the Total Power Radiometers, which includes a radiometer receiver 127 to collect the electromagnetic emissions and radiometer electronics 128 to control and process the data. The subject emissions could also include ultrasonic reflections from ultrasonic pulses transmitted by the Active Ultrasonic Module, which are converted in electronic signals 145. The emissions could also be the inductive nature of the subject as measured by the Metal Detection Module and converted into a voltage measurement 146. Additional sensing of the subject allows for development of a scan speed signal 147 by an optical mouse type scan speed sensor 125. This will enable indexing data to the spatial position on the subject. During a scan the relative readings from each sensor will be pre-processed by algorithms to classify and quantify the readings from each sensor. It will then be used by an anomaly detection algorithm to determine if a potential anomaly exists 148. If an anomaly is detected an alarm will be annunciated 149 and the approximate position, if known, will be shown on the detector's LED array. The alarm can be visual, via an audio speaker, via an audio headset, or by a vibration dependent on user preference. In parallel, data will be continuously stored in a Two Dimensional Spatial Data Matrix during the scan 150 and indexed by the position data from the scan speed sensor 125. The data will be organized by time received relative to the initiation of the scan and by position across the scan if relevant. At the completion of the scan the operator terminates the inspection 151 by depressing the input button switch, FIGS. 1 and 2, 105. At this point the entire Two Dimensional Spatial Data Matrix data will be available for analysis by the main processor board 124 with a lower detection threshold 152. The overall potential anomaly data from the entire scan can be used for this analysis. Thus a scattered set of anomalies on the subject that would not alarm individually could be analyzed collectively to generate a rescan alert. This process will require less than 1.0 second, enabling the next scan to be promptly initiated. If a rescan alert results, a specialized audio or visual signal, such as flashing all yellow LEDs on the LED Array 107 will suggest a slower speed rescan 153.

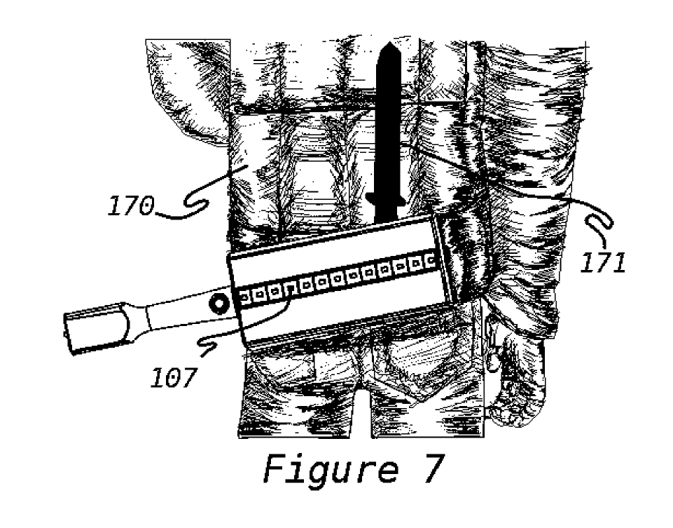

FIG. 7 illustrates scanning a person 170 being inspected with the embodiment of the contraband detector shown in FIGS. 1 to 6. The subject is depicted as concealing a nonmetallic knife 171 under the outer clothing. Measurements at each integration period during the scan will be stored in the Two Dimensional Spatial Data Matrix. The computer processor will be able to process this data in parallel with the data storage and will provide an alarm when the anomaly is sensed. The detector will also indicate on the LED array 107, the approximate position of the anomaly. A scan can be conducted at a 20 centimeter per second or higher rate. This enables two sweeps to complete a front or back torso scan in less than 5 seconds. This rapid scan capability is enabled by the multisensor approach of the detector and allows for a subject to be cleared in 30 seconds or less. The alarm thresholds can be adjusted by interfacing a PC resident program with the USB connector 118 provided in the Battery Pocket 104 to tailor the response to the particular operational requirement and perceived threat level.

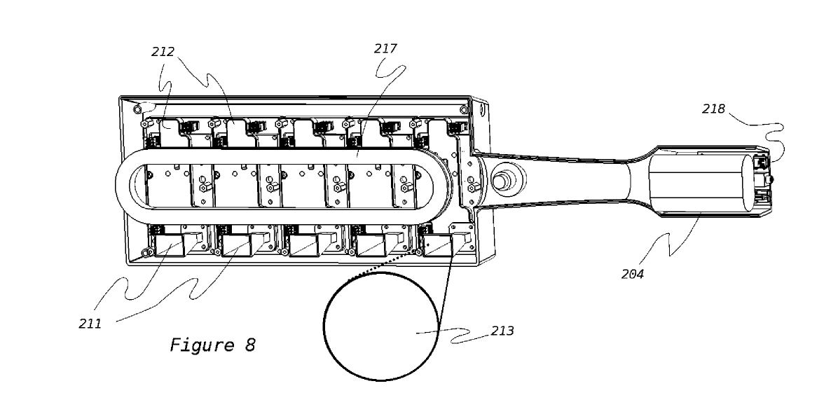

FIG. 8 illustrates another embodiment of the invention, with the plastic packaging removed. It includes a suite of more than two K or Ka band microwave Total Power Radiometers and a Metal Detection Module that includes an inductive coil and processing circuit. It shows that the radiometer feed horns 211 are connected to the radiometers 212 to collect microwave emissions from the subject being inspected. The Total Power Radiometers are much more robust and cost effective than higher frequency receivers. They are also not as susceptible to rigorous dimension tolerances required by W band radiometers, easing the ability to meet quality standards.

In the depiction of FIG. 8, a quantity of five Ka band feed horns with a 15 db gain are shown. Each will collect microwave emissions from a near circular target area 213 which can vary from 2.5 centimeters (1 inch) to 5 centimeters (2 inches) in diameter. This configuration provides the most efficient coverage and does not require the use of lenses as is often the case with W band and higher frequency sensors. Placed forward is the metal detector coil 217. It is located as close as possible to the front since its sensitivity falls off rapidly with target distance. This configuration facilitates a thin form factor detector that is easily handled during a scan. The USB Connector 218 shown in the Battery Pocket 204 enables adjustment of alarm thresholds and other user preferences (e.g. to silence the alarm) from a PC resident program.

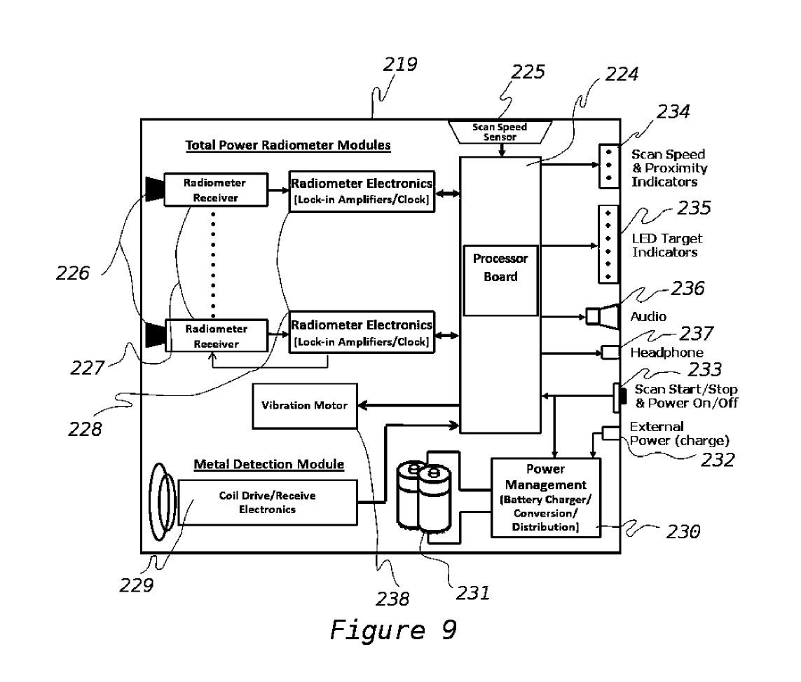

FIG. 9 depicts a Component Block Diagram 219 of the embodiment shown in FIG. 8. It includes the internal components and their interconnection. Providing input to the processor board is a scan speed sensor 225 such as one used for an optical mouse that enables location of received data relative to the initiation point of a scan. The array of feed horn antennae 226 provides input to the Total Power Radiometer for each channel. Each Total Power Radiometer includes a radiometer receiver 227 to collect the electromagnetic emissions and radiometer electronics 228 to control and process the data. Integrated data from each channel is sent to the main processor board 224 and time stamped. A metal detection coil 229 also sends amplitude data to the main processor board 224. The main processor board 224 is comprised of microcomputer and logic circuitry that is capable of executing an analysis program that will calculate a confidence factor that quantifies the likelihood of an anomaly. A power management circuit 230 distributes power and enables in-situ charging of the rechargeable batteries 231. An external power jack 232 enables external AC power to be connected to the power management circuit 230. A main switch 233 interfaces with the main process board 224 to turn power on or off as well as to initiate or terminate a scan. Indicators interfacing with the main processor board 224 include LED Scan Speed and Proximity Indicators 234, and a Target Indicator Array 235. The main processor board 224 analyzes the incoming signals to produce a confidence factor which is used, along with a user set threshold, to determine if an alarm should be activated. If so, Audio alarms 236, headset alarms, 237 and vibration alarms 238 are driven from the main processor board 224.

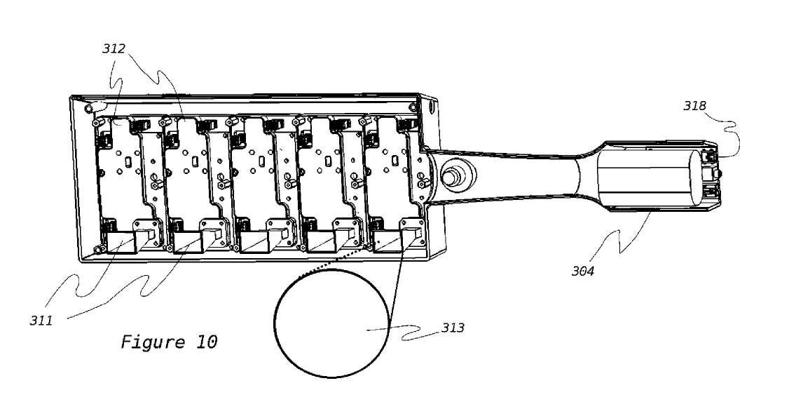

Another preferred embodiment of the multisensor detector is depicted in FIG. 10, with the plastic packaging removed. This embodiment includes a suite of more than two K or Ka band microwave Total Power Radiometers. It shows that the radiometer feed horns 311 are connected to the radiometers 312 to collect microwave emissions from the subject being inspected. The Total Power Radiometers are much more robust and cost effective than higher frequency receivers. They are also not as susceptible to rigorous dimension tolerances required by W band radiometers, easing the ability to meet quality standards.

In the depiction of FIG. 10, a quantity of five Ka band feed horns with a 15 db gain are shown. Each will collect microwave emissions from a near circular target area 313 which can vary from 2.5 centimeters (1 inch) to 5 centimeters (2 inches) in diameter. This configuration provides the most efficient coverage and does not require the use of lenses as is often the case with W band and higher frequency sensors. This configuration facilitates a thin form factor detector that is easily handled during a scan. The USB Connector 318 shown in the Battery Pocket 304 enables adjustment of alarm thresholds and other user preferences (e.g. to silence the alarm) from a PC resident program.

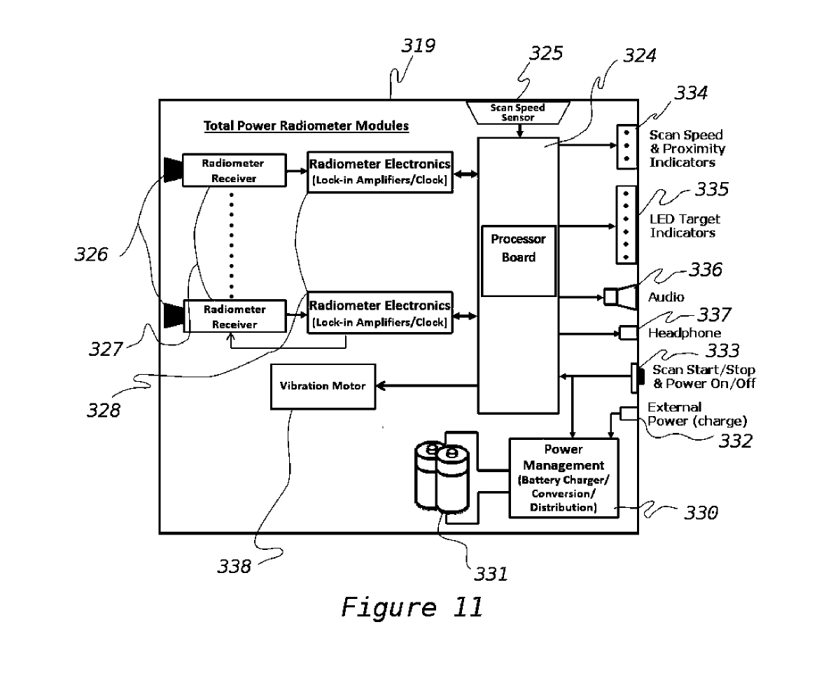

FIG. 11 depicts a Component Block Diagram 319 of the embodiment shown in FIG. 10. It includes the internal components and their interconnection. Providing input to the processor board is a scan speed sensor 325 such as one used for an optical mouse that enables location of received data relative to the initiation point of a scan. The array of feed horn antennae 326 provides input to the Total Power Radiometer for each channel. Each Total Power Radiometer includes a radiometer receiver 327 to collect the electromagnetic emissions and radiometer electronics 328 to control and process the data. Integrated data from each channel is sent to the main processor board 324 and time stamped. The main processor board 324 is comprised of microcomputer and logic circuitry that is capable of executing an analysis program that will calculate a confidence factor that quantifies the likelihood of an alarm. A power management circuit 330 distributes power and enables in-situ charging of the rechargeable batteries 331. An external power jack 332 enables external AC power to be connected to the power management circuit 330. A main switch 333 interfaces with the main process board 324 to turn power on or off as well as to initiate or terminate a scan. Indicators interfacing with the main processor board 324 include LED Scan Speed and Proximity Indicators 334, and a Target Indicator Array 335. The main processor board 324 analyzes the incoming signals to produce a confidence factor that is used, along with a user set threshold, to determine if an alarm should be activated. If so, Audio alarms 336, headset alarms, 337 and vibration alarms 338 are driven from the main processor board 324.

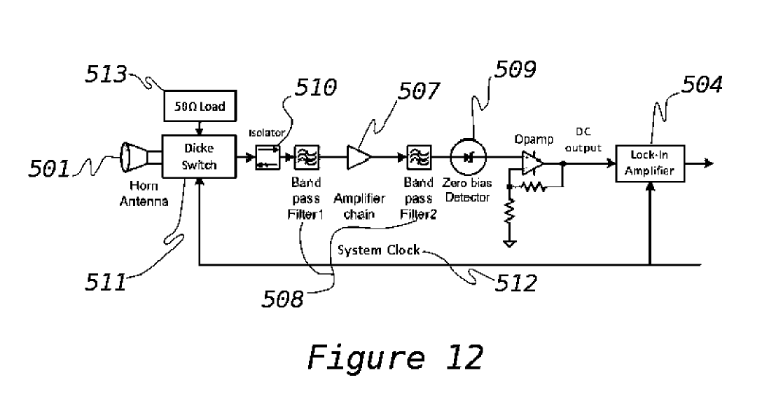

FIG. 12 illustrates a Circuit Block Diagram of a single TPR circuit of the embodiment shown in FIGS. 1 to 6 and FIGS. 8 to 12. The receiver operates below the W-band to increase the field of view of individual sensor elements to reduce the number of channels and therefore the system cost. It shows a 15 dB or higher K or Ka Band feed horn antenna 501 to limit the Field of View of the emissions being received from the subject being inspected. The total radiation received at the antenna is the radiation from an object due to its physical temperature being greater than absolute zero, and is a function of its temperature, emissivity, and reflectivity. Emissivity and reflectivity are unique properties of an object and vary for each material and environment. Thus different materials on the subject would provide a discernible contrast with the human body transporting them. The feed horn antenna is connected through an antenna launch to an electronic switch 511 called a Dicke Switch (named for its late inventor, the noted astrophysicist Robert Dicke of Princeton University). The system clock signal line 512, which may be generated with the Main Processor or a separate clock, controls the Dicke Switch causing the input signal to the radiometer to oscillate between the feed horn antenna signal and a reference resistive load 513. The oscillation rate of the Dicke Switch is typically in the 20 Hz to 1000 Hz range and can be optimized for any specific Total Power Radiometer configuration. The system clock 512 also feeds forward to synchronize a Lock-in Amplifier 504 that uses the signal drift observed from the 50Ω resistive load 513 to quantify the real time radiometer drift and use that information to provide a means of self-calibration to extract any inherent instability in the radiometer.

The output signal from the Dicke Switch 511 is fed through an isolator 510 to match impedance to a K or Ka Band Amplifier Chain that amplifies the received signal. The signal passes through band pass filters 508 on either side of amplifier chain to reduce noise. The filtered signal passed to a Zero Bias Detector 509 which provides a DC Signal proportional to the Total Power received by the TPR. The Lock-in Amplifier 504 then provides this DC signal to the Main Processor Board 124 for processing.

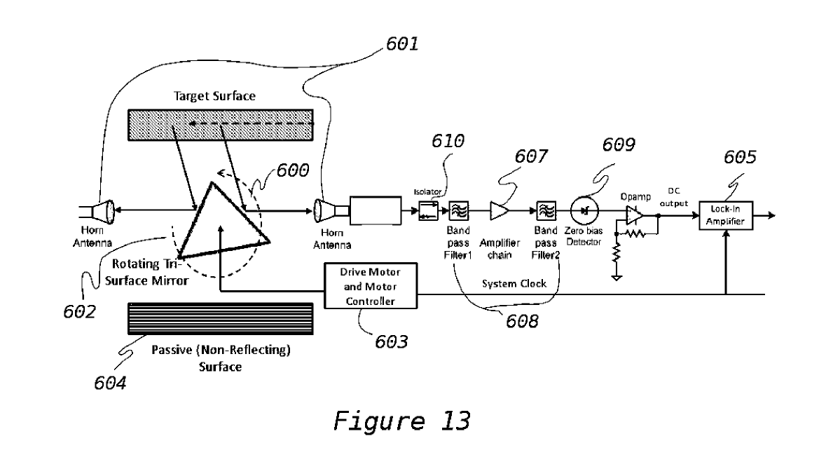

FIG. 13 illustrates the Circuit Block Diagram of another preferred embodiment of the multisensor detector that uses a mirror to sweep the fields of view 600 of two Total Power Radiometers, one from each end of the detector housing. This method enables reduction to two Total Power Radiometers in the detector resulting in cost and weight reductions. Two K or Ka band feed horn antennae 601 are employed viewing along the length of the detector in opposite directions. A rotating mirror 602 driven by an electric motor 603 moves the field of view of the mirror through a 45° to 90° arc to cover a wedge of the subject. The rotating mirror 602 will also reflect off of a passive surface 604 inside the detector to provide a consistent signal that can be used by the Lock-in Amplifier 605 to extract any inherent instability in the TPR. The signal will then be processed by the Ka-Band Amplifier chain 607 and band pass filters 608 before being detected by a Zero Bias Detector 609 to provide a signal proportional to the total power received by the TPR. This signal will be sent to a Lock-in Amplifier 605 that uses the signal representing the passive surface to quantify the radiometer drift in real time and use that information to provide a means of self-calibration to extract any inherent instability in the TPR. An isolator 610 is used at the front of the detection chain as indicated in FIG. 12 to alleviate near field impedance differences that can occur which cause the signal to vary with distance, which can cause false positive alarms. A signal representing the position of each rotating mirror is sent to the Main Processor Board 124 and the overall received signal is integrated over a fixed segment of the scan. The information stored in the Two Dimensional Spatial Data Matrix is similar to that stored in the embodiment depicted in FIGS. 1 to 6. This embodiment will reduce cost and complexity by eliminating the Dicke Switch and reducing the number of Total Power Radiometers, but the maximum scan speed will be approximately one half of the embodiments with a full array of radiometers.

A particular embodiment of the invention shown in FIGS. 1 to 6 employs a TPR that measures the electromagnetic emissions from 31 GHz to 34 GHz.

Another particular embodiment of the invention shown in FIGS. 1 to 6 employs a TPR that measures the electromagnetic emissions from 37 GHz to 40 GHz.

Another particular embodiment of the invention shown in FIGS. 1 to 6 employs a TPR that measures the electromagnetic emissions from 27 GHz to 30 GHz.

Another particular embodiment of the invention shown in FIGS. 1 to 6 employs a TPR that measures the electromagnetic emissions from 21 GHz to 24 GHz.

A particular embodiment of the invention shown in FIGS. 8 to 12 employs a TPR that measures the electromagnetic emissions from 32 GHz to 35 GHz.

Another particular embodiment of the invention shown in FIGS. 8 to 12 employs a TPR that measures the electromagnetic emissions from 37 GHz to 40 GHz.

Another particular embodiment of the invention shown in FIGS. 8 to 12 employs a TPR that measures the electromagnetic emissions from 27 GHz to 30 GHz.

Another particular embodiment of the invention shown in FIGS. 8 to 12 employs a TPR that measures the electromagnetic emissions from 21 GHz to 24 GHz.

A particular embodiment of the invention shown in FIG. 13 employs a TPR that measures the electromagnetic emissions from 31 GHz to 34 GHz.

Another particular embodiment of the invention shown in FIG. 13 employs a TPR that measures the electromagnetic emissions from 37 GHz to 40 GHz.

Another particular embodiment of the invention shown in FIG. 13 employs a TPR that measures the electromagnetic emissions from 27 GHz to 30 GHz.

Another particular embodiment of the invention shown in FIG. 13 employs a TPR that measures the electromagnetic emissions from 21 GHz to 24 GHz.

A processing system, as used herein, is intended to embody electronic circuitry that processes data and/or signals according to a set of instructions, where these instructions may be embodied in hardware or software, and may include without limitation central processing units, microprocessors, microcomputers, logic circuitry, integrated circuits, arithmetic logic units, and control units.

It should be understood that while the preferred embodiments of the invention are described in some detail herein, the present disclosure is made by way of example only and that variations and changes thereto are possible without departing from the subject matter coming within the scope of the following claims, and a reasonable equivalency thereof, which claims I regard as my invention.

That which is claimed:

1. A handheld multisensory contraband detector comprising.
a plurality of K or Ka band Total Power Radiometers, where each Total Power Radiometer measures the power of natural microwave emissions from different spatial locations of a subject,
an Active Ultrasonic Module, where the Active Ultrasonic Module comprises an ultrasonic transmitter, an ultrasonic sensor, and a phased array processer, where the phased array processor provides the position of ultrasonic return signals obtained by the ultrasonic sensor,
a Metal Detection Module,
a processor board, wherein the processor board processes signals from the Total Power Radiometers, phased array processor, and metal detector, where the processor board calculates a confidence factor of whether or not an anomaly on a subject has been encountered, and
an enclosure package, where the enclosure package provides environmental protection to the detectors, sensors, and processors of the handheld multisensory contraband detector.

2. The handheld multisensory contraband detector of claim 1, wherein measurements provided by the plurality of Total Power Radiometers are stored in a Two Dimensional Spatial Data Matrix.

3. An apparatus for detecting anomalous signals from a subject being scanned, the apparatus being comprised of:
an aligned suite of detectors comprised of more than two K or Ka band Total Power Radiometers to measure the power of natural microwave emissions from different spatial locations of the subject;
a processing system to monitor variances between each Total Power Radiometer to determine if an anomaly is present during the scan; and
an enclosure package to provide environmental protection to the Total Power Radiometers.

4. The apparatus of claim 3, further comprising a system to integrate the variances from each Total Power Radiometer over a discrete time slice required to transverse a small section of a body during a scan, and
wherein the processing system to monitor variances between each Total Power Radiometer also measures variances of each Total Power Radiometer between discrete time slices.

5. The apparatus of claim 3, further comprising:
a click scan Start/Stop button, wherein depressing the click scan Start/Stop button indicates the beginning and end of a scan;
a scan speed sensor;
a processing system to integrate the signal strength from each Total Power Radiometer over a discrete time slice required to transverse a small section of a body during a scan;
a processing system to time stamp and store the integrated signal strength for each Total Power Radiometer indexed by its corresponding time slice in accessible digital memory;
a processing system to convert a temporal variance between each integration period along with an instantaneous scan speed into a spatial dimension roughly orthogonal to the axis of the aligned suite of detectors;
a processing system to map the time related integrated signal strength of each Total Power Radiometer onto a Two Dimensional Spatial Data Matrix; and
wherein the processing system to facilitate analysis of the Two Dimensional Spatial Matrix produces an alert signal based on the Two Dimensional Spatial Data Matrix analysis to suggest a repeat scan at a slower scan speed.

6. The apparatus of claim 5, further comprising an alarm system, where the alarm system comprises light emitting diodes, a speaker, a headset, a vibration alarm, or any combination thereof, wherein the alarm system is activated to indicate an anomaly with a spot size larger than a user set threshold.

7. The apparatus of claim 5, further comprising a bank of light emitting diodes, wherein the bank of light emitting diodes is used to indicate the need to move closer or further from a subject being inspected.

8. The apparatus claim 5, further comprising an array of light emitting diodes, wherein the array of light emitting diodes is used to indicate the relative position of a detected anomaly.

9. The apparatus of claim 3, further comprising an Active Ultrasonic Module, where the Active Ultrasonic Module comprises an ultrasonic transmitter and an ultrasonic sensor.

10. The apparatus of claim 9, wherein the Active Ultrasonic Module further comprises a phased array processer, where the phased array processor provides the position of ultrasonic return signals obtained by the ultrasonic sensor from a subject being inspected.

11. The apparatus of claim 5, further comprising Active Ultrasonic Module and a processing system to time stamp ultrasonic data collected during a scan from the Active Ultrasonic Module, where the Active Ultrasonic Module comprises an ultrasonic transmitter and an ultrasonic sensor, wherein the time stamped ultrasonic data is used in conjunction with data in the Two Dimensional Spatial Data Matrix to provide a higher probability of anomaly detection at the completion of a scan.

12. The apparatus of claim 11, wherein the Active Ultrasonic Module further comprises a phased array processer, where the phased array processor provides the position of ultrasonic return signals obtained by the ultrasonic sensor from a subject being inspected.

13. The apparatus of claim 3, further comprising a metal detection module.

14. The apparatus of claim 5, further comprising a metal detection module and a processing system to time stamp metal detection data collected during a scan from the metal detection module, wherein the time stamped metal detection data is used in conjunction with data in the Two Dimensional Spatial Data Matrix to provide a higher probability of anomaly detection at the completion of a scan

15. A handheld multisensor contraband detector, comprised of:
two K or Ka band Total Power Radiometers to measure natural microwave emissions;
a rotating mirror to sweep a scanning zone from each Total Power Radiometer across the surface of a subject being inspected from each end of the detector;
a high speed switching system to define a discrete time slice required for the scanning zone being swept by the rotating mirror to transverse a defined small angle of the subject being inspected;
a processing system to integrate the signal strength over the discrete time slice required for the scanning zone being swept by the rotating mirror to transverse a small angle of the subject being inspected;
a processing system to time stamp and store the integrated signal strength for each scanning zone swept by the rotating mirror in accessible digital memory;
a click scan Start/Stop button to indicate the beginning and end of a scan;
a scan speed sensor;
a processing system to map time related variance of the signal strength of each scanning zone onto a Two Dimensional Spatial Matrix to determine if an anomaly is present;
a processing system to facilitate analysis of the Two Dimensional Spatial Data Matrix upon completion of a scan to provide a higher probability of anomaly detection; and
an enclosure package to provide environmental protection to the sensors and processing systems contained therein.

16. The apparatus of claim 15, further comprising an alarm system, where the alarm system comprises light emitting diodes, a speaker, a headset, a vibration alarm, or any combination thereof, wherein the alarm system is activated to indicate an anomaly with a spot size larger than a user set threshold.

17. The apparatus of claim 15, further comprising a bank of light emitting diodes, wherein the bank of light emitting diodes is used to indicate the need to move closer or further from a subject being inspected.

18. The apparatus claim 15, further comprising an array of light emitting diodes, wherein the array of light emitting diodes is used to indicate the relative position of a detected anomaly.

19. The apparatus of claim 15, further comprising an active ultrasonic module and a processing system to time stamp ultrasonic data collected during a scan from the active ultrasonic module, where the active ultrasonic module comprises an ultrasonic transmitter, an ultrasonic sensor, and a phased array processer, where the phased array processor provides the position of ultrasonic return signals obtained by the ultrasonic sensor from a subject being inspected, wherein the time stamped ultrasonic data is used in conjunction with data in the Two Dimensional Spatial Data Matrix to provide a higher probability of anomaly detection at the completion of a scan.

20. The apparatus of claim 15, further comprising a metal detection module and a processing system to time stamp metal detection data collected during a scan from the metal detection module, wherein the time stamped metal detection data is used in conjunction with data in the Two Dimensional Spatial Data Matrix to provide a higher probability of anomaly detection at the completion of a scan
